(19) United States
(12) Patent Application Publication
(10) Pub. No.: US 2008/0277787 A1
(43) Pub. Date: Nov. 13, 2008

(54) METHOD AND PAD DESIGN FOR THE REMOVAL OF BARRIER MATERIAL BY ELECTROCHEMICAL MECHANICAL PROCESSING

(76) Inventors: Feng Q. Liu, San Jose, CA (US); Alain Duboust, Sunnyvale, CA (US); Yan Wang, Sunnyvale, CA (US); Wei-Yung Hsu, Santa Clara, CA (US); Tianbo Du, Beaverton, OR (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/746,135

(22) Filed: May 9, 2007

(51) Int. Cl. H01L 23/485; H01L 21/4763

(52) U.S. Cl. 257/741; 257/774; 438/633; 257/E23.011; 257/E21.487; 257/E21.495

(57) ABSTRACT

A method and apparatus for processing barrier and metals disposed on a substrate in an electrochemical mechanical planarizing system are provided. In certain embodiments a method for electroprocessing a substrate is provided. The method comprises contacting the substrate with the non-conductive surface of a polishing pad assembly, establishing a first electrically conductive path through an electrolyte between an exposed layer of barrier material and a first electrode, establishing a second electrically conductive path through the electrolyte between the exposed layer of barrier material and a second electrode, applying a voltage to the first electrode to cause a voltage drop between the substrate and the second electrode, and removing the barrier material from the substrate.

### BACKGROUND OF THE INVENTION

1. Field of the Invention

Embodiments of the present invention as recited by the claims generally relate to a method and processing apparatus for planarizing or polishing a substrate. More particularly, the invention relates to a method and a polishing pad for planarizing or polishing a semiconductor substrate by electrochemical mechanical polishing.

2. Description of the Related Art

In the fabrication of integrated circuits and other electronic devices on substrates, multiple layers of conductive, semiconductive, and dielectric materials are deposited on or removed from a substrate, such as a semiconductor wafer. As layers of materials are sequentially deposited and removed, the substrate may become non-planar and require planarization, in which previously deposited material is removed from the substrate to form a generally even, planar or level surface. The process is useful in removing undesired surface topography and surface defects, such as rough surfaces, agglomerated materials, crystal lattice damage and scratches. The planarization process is also useful in forming features on the substrate by removing excess deposited material used to fill the features and to provide an even or level surface for subsequent deposition and processing.

Electrochemical Mechanical Planarization (Ecmp) is one exemplary process which is used to remove materials from the substrate. Ecmp typically uses a pad having conductive properties and combines physical abrasion with electrochemical activity that enhances the removal of materials. The pad is attached to an apparatus having a rotating platen assembly that is adapted to couple the pad to a power source. The apparatus also has a substrate carrier, such as a polishing head, that is mounted on a carrier assembly above the pad that holds a substrate. The polishing head places the substrate in contact with the pad and is adapted to provide downward pressure, controllably urging the substrate against the pad. The pad is moved relative to the substrate by an external driving force and the polishing head typically moves relative to the moving pad. A chemical composition, such as an electrolyte, is typically provided to the surface of the pad which enhances electrochemical activity between the pad and the substrate. The Ecmp apparatus may affect abrasive and/or polishing activity from frictional movement while the electrolyte combined with the conductive properties of the pad selectively removes material from the substrate.

In many conventional systems, Ecmp of the conductive film is followed by a conventional chemical mechanical processing for barrier removal. This dichotomy of processing (e.g., Ecmp and CMP on a single system) requires divergent utilities and process consumables, resulting in higher cost of ownership. Moreover, as most Ecmp processes utilize lower contact pressure between the substrate being processed and a processing surface, the heads utilized to retain the substrate during processing do not provide robust processing performance when utilized for conventional CMP processes, which typically have high contact pressures, which results in high erosion of conductive material disposed in trenches or other features. As the removal rate of low pressure conventional CMP barrier layer processing is generally less than about 100 Å/min, conventional CMP processing of barrier materials using low pressure is not suitable for large scale commercialization. Thus in some systems, Ecmp is also used to remove barrier materials. However, because of the inertness of barrier materials, the removal current during Ecmp is very low. Although the removal current can be increased by increasing the applied voltage, an applied voltage that is too high results in a very large leakage current between the contact materials. This large leakage current results in poor contact between the substrate and the conductive pad materials.

Thus, there is a need for an improved method and apparatus for electrochemical processing of metal and barrier materials.

### SUMMARY OF THE INVENTION

Embodiments of the invention as recited in the claims generally provide a processing apparatus and a method for processing barrier and metals disposed on a substrate in an electrochemical mechanical planarizing system. In certain embodiments a pad assembly for processing a substrate is provided. The pad assembly comprises a first conductive layer, a first isolation layer coupled with the first conductive layer, a second conductive layer coupled with the first isolation layer, and a second isolation layer coupled with the second conductive layer, wherein the second isolation layer forms a processing surface adapted to contact the substrate surface.

In certain embodiments a method for electroprocessing a substrate is provided. The method comprises contacting the substrate with the non-conductive surface of a polishing pad assembly, establishing a first electrically conductive path through an electrolyte between an exposed layer of barrier material and a first electrode, establishing a second electrically conductive path through the electrolyte between the exposed layer of barrier material and a second electrode, applying a voltage to the first electrode to cause a voltage drop between the substrate and the second electrode, and removing the barrier material from the substrate.

In certain embodiments a method for electroprocessing a substrate is provided. The method comprises providing a pad assembly comprising a first non-conductive layer, a first conductive layer coupled with the first non-conductive layer, a second conductive layer, and a second non-conductive layer disposed between the first conductive layer and the second conductive layer. The substrate is contacted with the first non-conductive layer of the polishing pad assembly. A first electrically conductive path is established between an exposed layer of barrier material on the substrate and the first conductive layer. A second electrically conductive path is established through the electrolyte between the exposed layer of barrier material on the substrate and the second conductive layer. A positive voltage is applied to the first conductive layer. A negative voltage is applied to the second conductive layer. The barrier material layer is removed from the substrate.

In certain embodiments a pad assembly for processing a substrate is provided. The pad assembly comprises a first conductive layer and a plurality of discrete members coupled to the first conductive layer. The plurality of discrete members comprise a first isolation layer coupled to the first conductive layer, a second conductive layer coupled to the first isolation layer, and a second isolation layer coupled to the second conductive layer, wherein the second isolation layer forms a processing surface adapted to contact the substrate.

### BRIEF DESCRIPTION OF THE DRAWINGS

So that the manner in which the above recited features of the present invention can be understood in detail, a more particular description of the invention, briefly summarized above, may be had by reference to certain embodiments, some of which are illustrated in the appended drawings. It is to be noted, however, that the appended drawings illustrate only certain embodiments and are therefore not to be considered limiting of its scope, for the invention may admit to other equally effective embodiments.

FIG. 1 is a top view of an exemplary processing system;

FIG. 2A is a sectional view of an exemplary Ecmp station;

FIG. 2B is an enlarged partial sectional view of an exemplary portion of the pad assembly shown in FIG. 2A;

FIG. 3 is a top view of an exemplary pad assembly;

FIG. 4 is a schematic side view of a portion of the exemplary pad assembly of FIG. 3 taken along line 4-4;

FIG. 5 is a top view of an exemplary pad assembly;

FIG. 6 is a schematic side view of a portion of the exemplary pad assembly of FIG. 5 taken along line 6-6;

FIG. 7 is a flow diagram of an exemplary method for electroprocessing conductive and barrier materials;

FIG. 8 depicts a graph illustrating current verse time for one embodiment of an exemplary electroprocessing method; and

FIG. 9 depicts a graph illustrating current verse voltage curve for copper polished in an electrolyte with abrasion.

To facilitate understanding, identical reference numerals have been used, where possible, to designate identical elements that are common to the figures. It is contemplated that elements and/or process steps of one or more embodiments may be beneficially incorporated in one or more other embodiments without additional recitation.

### DETAILED DESCRIPTION

The words and phrases used in the present invention should be given their ordinary and customary meaning in the art by one skilled in the art unless otherwise further defined. Certain embodiments provide a method and processing apparatus for removal of conductive and barrier materials from a substrate.

As used herein, the term “electrochemical mechanical polishing” (Ecmp) generally refers to planarizing a substrate by the application of electrochemical activity, mechanical activity, and chemical activity to remove material from a substrate surface.

As used herein, the term “electropolishing” generally refers to planarizing a substrate by the application of electrochemical activity.

As used herein, the term “anodic dissolution” generally refers to the application of an anodic bias to a substrate directly or indirectly which results in the removal of conductive material from a substrate surface and into a surrounding polishing composition.

As used herein, the term “polishing composition” generally refers to a composition that provides ionic conductivity, and thus, electrical conductivity, in a liquid medium, which generally comprises materials known as electrolyte components.

As used herein, the term “substrate” generally refers to any substrate or material surface formed on a substrate upon which film processing is performed, such as silicon wafers used in semiconductor processing. For example, a substrate on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes.

The electrochemical mechanical polishing process may be performed in a process apparatus, such as a platform having one or more polishing stations adapted for electrochemical mechanical polishing processes. The one or more polishing stations may be adapted to perform conventional chemical mechanical polishing. A platen for performing an electrochemical mechanical polishing process may include a polishing article, a first electrode, and a second electrode. Examples of suitable systems that can be adapted to benefit from the invention include MIRRA®, MIRRA MESA®, REFLEXION®, REFLEXION® LK, and REFLEXION LK Ecmp™ processing systems, all of which are commercially available from Applied Materials, Inc., of Santa Clara, Calif. The following apparatus description is illustrative and should not be construed or interpreted as limiting the scope of the invention.

### Apparatus

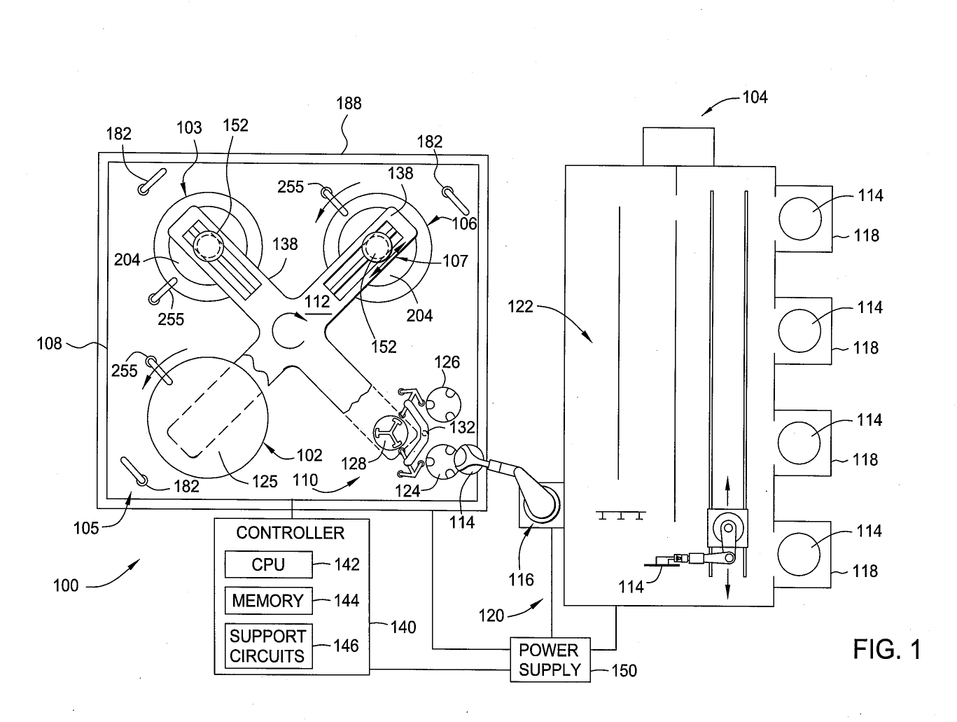

FIG. 1 is a top view of an exemplary processing system 100 having a planarizing module 105 that is suitable for electrochemical mechanical polishing and chemical mechanical polishing. The planarizing module 105 includes at least a first electrochemical mechanical planarization (Ecmp) station 102, and optionally, at least one conventional chemical mechanical planarization (CMP) station disposed in an environmentally controlled enclosure 188. An example of a processing system 100 that may be adapted to practice the invention is the REFLEXION LK Ecmp™ system available from Applied Materials, Inc. located in Santa Clara, Calif. Other suitable planarizing modules may also be adapted to practice the invention.

The planarizing module 105 shown in FIG. 1 includes a first Ecmp station 102, a second Ecmp station 103, and a third Ecmp station 106. It is to be understood that the invention is not limited to this configuration and that all of the stations 102, 103, and 106 may be adapted to use an Ecmp process or a CMP process to remove various layers deposited on the substrate. Alternatively, the planarizing module 105 may include two stations that are adapted to perform a CMP process while another station may perform an Ecmp process. In one exemplary process, a substrate having feature definitions lined with a barrier layer and filled with a conductive material disposed over the barrier layer may have the conductive material removed in two steps in the two Ecmp stations 102, 103, with the barrier layer processed in the third Ecmp station 106 to form a planarized surface on the substrate. It is to be noted that the stations 102, 103, and 106 in any of the combinations mentioned above may also be adapted to deposit a material on a substrate by an electrochemical and/or an electrochemical mechanical plating process.

The exemplary processing system 100 generally includes a base 108 that supports one or more Ecmp stations 102, 103, and 106, a transfer station 110, conditioning devices 182, and a carousel 112. The transfer station 110 generally facilitates transfer of substrates 114 to and from the system 100 via a loading robot 116. The loading robot 116 typically transfers substrates 114 between the transfer station 110 and an interface 120 that may include a cleaning module 122, a metrology device 104 and one or more substrate storage cassettes 118.

The transfer station 110 comprises at least an input buffer station 124, an output buffer station 126, a transfer robot 132, and a load cup assembly 128. The loading robot 116 places the substrate 114 onto the input buffer station 124. The transfer robot 132 has two gripper assemblies, each having pneumatic gripper fingers that hold the substrate 114 by the substrate's edge. The transfer robot 132 lifts the substrate 114 from the input buffer station 124 and rotates the gripper and substrate 114 to position the substrate 114 over the load cup assembly 128, then places the substrate 114 down onto the load cup assembly 128. An example of a transfer station that may be used is described in U.S. Pat. No. 6,156,124, issued Dec. 5, 2000, entitled “Wafer Transfer Station for a Chemical Mechanical Polisher,” incorporated herein by reference to the extent it is not inconsistent with this application.

The carousel 112 generally supports a plurality of carrier heads 186, each of which retains one substrate 114 during processing. The carousel 112 moves the carrier heads 186 between the transfer station 110 and stations 102, 103 and 106. One carousel that may used is generally described in U.S. Pat. No. 5,804,507, issued Sep. 8, 1998, entitled “Radially Oscillating Carousel Processing System for Chemical Mechanical Polishing,” which is hereby incorporated by reference to the extent it is not inconsistent with this application.

The carousel 112 is centrally disposed on the base 108. The carousel 112 typically includes a plurality of arms 138 and each arm 138 generally supports one of the carrier heads 186. Two of the arms 138 depicted in FIG. 1 are shown in phantom so that the transfer station 110 and a processing surface 125 of Ecmp station 102 may be seen. The carousel 112 is indexable such that the carrier head 186 may be moved between stations 102, 103, 106, and the transfer station 110 in a sequence defined by the user.

Generally the carrier head 186 retains the substrate 114 while the substrate 114 is disposed in the Ecmp stations 102, 103, or 106. The arrangement of the Ecmp stations 102, 103, and 106 on the system 100 allow for the substrate 114 to be sequentially processed by moving the substrate between stations while being retained in the same carrier head 186.

To facilitate control of the processing system 100 and processes performed thereon, a controller 140 comprising a central processing unit (CPU) 142, memory 144 and support circuits 146 is connected to the processing system 100. The CPU 142 may be one of any form of computer processor that can be used in an industrial setting for controlling various drives and pressures. The memory 144 is connected to the CPU 142. The memory 144, or computer-readable medium, may be one or more of readily available memory such as random access memory (RAM), read only memory (ROM), floppy disk, hard disk, or any other form of digital storage, local or remote. The support circuits 146 are connected to the CPU 142 for supporting the processor in a conventional manner. These circuits include cache, power supplies, clock circuits, input/output circuitry, subsystems, and the like.

Power to operate the processing system 100 and/or the controller 140 is provided by a power supply 150. Illustratively, the power supply 150 is shown connected to multiple components of the processing system 100, including the transfer station 110, the factory interface 120, the loading robot 116 and the controller 140.

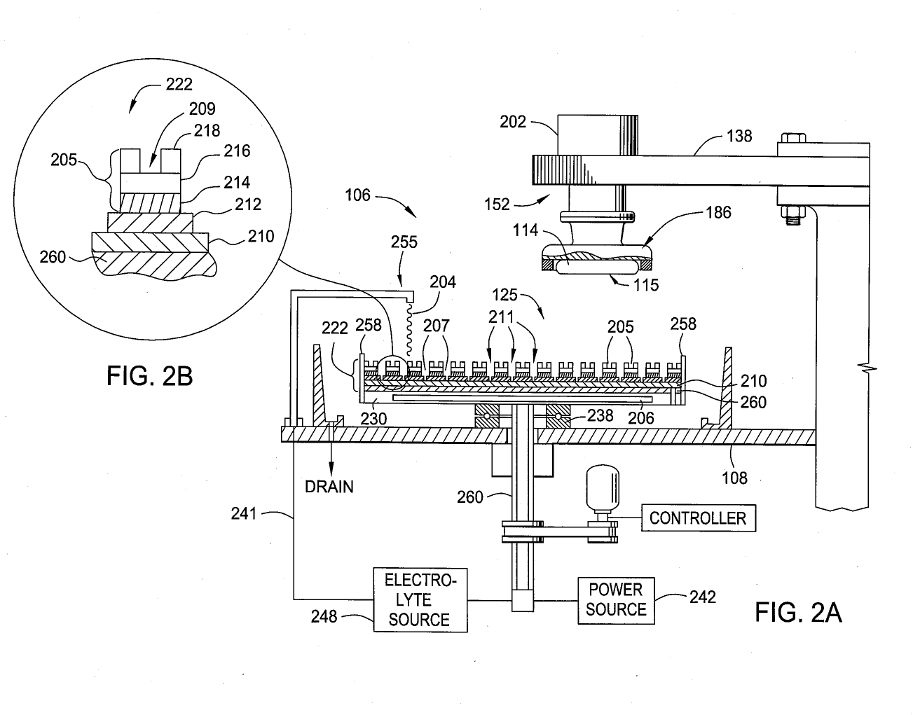

FIG. 2A depicts a sectional view of an exemplary Ecmp station 106 depicting a carrier head assembly 152 positioned over a platen assembly 230. The carrier head assembly 152 generally comprises a drive system 202 coupled to a carrier head 186. The drive system 202 may be coupled to the controller 140 (FIG. 1) that provides a signal to the drive system 202 for controlling the rotational speed and direction of the carrier head 186. A processing pad assembly 222 is shown coupled to the platen assembly 230. The processing pad assembly 222 is configured to receive an electrical bias to perform a plating process and/or an electrochemical mechanical polishing/planarizing process. The drive system 202 generally provides at least rotational motion to the carrier head 186 and additionally may be actuated toward the Ecmp station 106 such that a front side 115 of the substrate 114, retained in the carrier head 186, may be disposed against the pad assembly 222 of the Ecmp station 106 during processing. Typically, the substrate 114 and processing pad assembly 222 are rotated relative to one another in an Ecmp process to remove material from the front side 115 of the substrate 114. Depending on process parameters, the carrier head 186 is rotated at a rotational speed greater than, less than, or equal to, the rotational speed of the platen assembly 230. The carrier head assembly 152 is also capable of remaining rotationally fixed and may move in a path indicated by arrow 107 in FIG. 1 during processing. The carrier head assembly 152 may also provide an orbital or a sweeping motion across the processing surface 125 during processing.

In certain embodiments, the processing pad assembly 222 may be adapted to releasably couple to an upper surface 260 of the platen assembly 230. The pad assembly 222 may be bound to the upper surface 260 by the use of pressure and/or temperature sensitive adhesives, allowing replacement of the pad assembly 222 by peeling the pad assembly from the upper surface 260 and applying fresh adhesive prior to placement of a new pad assembly 222. In other embodiments, the upper surface 260 of the platen assembly 230, having the processing pad assembly 222 coupled thereto, may be adapted to releasably couple to the platen assembly 230 via other methods, such as fasteners, vacuum and magnets, among other retaining methods.

The platen assembly 230 is disposed on a base 108 and is supported above the base 108 by a bearing 238 so that the platen assembly 230 may be rotated relative to the base 108. The platen assembly 230 may be fabricated from a rigid material, such as a metal or rigid plastic, and in one embodiment the platen assembly 230 has an upper surface 260 that is fabricated from or coated with a dielectric material, such as CPVC. The platen assembly 230 may have a circular, rectangular or other plane form and the upper surface 260 may resemble that plane form.

Electrolyte may be provided from the source 248, through appropriate plumbing and controls, such as conduit 241, to nozzle 255 positioned above the processing pad assembly 222 of the ECMP station 102. Optionally, a plenum 206 may be defined in the platen assembly 230 for containing an electrolyte and facilitating ingress and egress of the electrolyte to the pad assembly 222. A detailed description of an exemplary planarizing assembly suitable for using the present invention can be found in U.S. Pat. No. 7,029,365, entitled “Pad Assembly for Electrochemical Mechanical Processing,” issued Apr. 18, 2006, which is incorporated herein by reference to the extent it is not inconsistent with this application.

In the embodiment shown in FIG. 2A, an electrolyte 204 is provided from a nozzle 255. The electrolyte 204 may form a bath that is bounded by the platen lip 258 adapted to contain a suitable processing level of electrolyte 204 while rotating. Alternatively, the electrolyte may be provided by the nozzle 255 continuously or at intervals to maintain a suitable level of electrolyte in the processing pad assembly 222. After the electrolyte has reached its processing capacity and is ready for replacement, the platen assembly 230 may be rotated at a higher rotational speed and the spent electrolyte is released by the action of centrifugal force over the platen lip 258. In certain embodiments, the platen assembly 230 is rotated at a higher rotational speed the spent electrolyte is released through perforations in the platen lip 258 that may be opened and closed by an operator or controlled by rotational speed. Alternatively or additionally, spent electrolyte may be released through at least one perforation performing as a drain formed through various layers of the pad assembly 222 and/or the platen assembly 230.

FIG. 2B is an enlarged partial sectional view of a portion of the pad assembly 222 shown in FIG. 2A. In certain embodiments, the pad assembly 222 generally includes a plurality of posts or discrete members 205 coupled to a first conductive layer 212. The plurality of discrete members 205 may take the form of post extensions extending upward from the first conductive layer 212 and generally include a second conductive layer 216, a first isolation layer 214 to electrically isolate the second conductive layer 216 from the first conductive layer 212, and a second isolation layer 218 to electrically isolate the second conductive layer 216 from the front side 115 of the substrate 114.

The discrete member 205 may include any geometrical shape, such as ovals, rectangles, triangles, hexagons, octagons, or combinations thereof. A processing surface 125 is generally defined by an upper portion of each discrete member 205, which is also the upper surface of the second isolation layer 218. The second isolation layer 218 forms a first aperture 209 which allows for the exposure of the second conductive layer 216 to the electrolyte 204 during processing. The first aperture 209 may take any geometrical form, such as ovals, circles, rectangles, hexagons, octagons, triangles, or combinations thereof and may be formed by compression molding and/or embossment of the second isolation layer 218. The second isolation layer 218 electrically isolates the second conductive layer 216 from the side 115 of the substrate 114. A second plurality of apertures 211 are generally defined by the open areas between the plurality of discrete members 205 and each of the second plurality of apertures 211 define a functional cell 207 which is configured to receive an electrolyte. Each of the functional cells 207 are adapted to perform as an electrochemical cell when the electrolyte 204 is provided to the pad assembly 222 and a differential electrical bias is applied to the first conductive layer 212 and the second conductive layer 216. In certain embodiments, the second plurality of apertures 211, or the plurality of functional cells 207, define an open area between about 5 percent to about 90 percent, for example, between about 20 percent to about 70 percent.

The second isolation layer 218 may be made of an insulating material that is configured to electrically isolate the side 115 of the substrate 114 from the second conductive layer 216. The second isolation layer 218 may have a hardness of about 20 Shore A to about 90 Shore A. The second isolation layer 218 is generally between about 0.1 mm and about 2 mm thick. The second isolation layer 218 may be fabricated from polymeric materials, such as polyurethane and polyurethane mixed with fillers, polycarbonate, polyphenylene sulfide (PPS), ethylene-propylene-diene-methylene (EPDM), TEFLON® polymers, polyethylene terephthalate (PET), or combinations thereof. The second isolation layer 218 may also be made of other polishing materials used in polishing substrate surfaces, such as open or closed-cell foamed polymers, elastomers, felt, impregnated felt, plastics, and like materials compatible with the processing chemistries. Alternatively or additionally, abrasive particles may be interspersed within the second isolation layer 218 to enhance removal of conductive, residual, and/or barrier material from the front side 115 of the substrate 114. Examples of abrasive particles that may be used are conductive metals and/or ceramic materials, such as aluminum, ceria, oxides thereof and derivatives thereof, and combinations thereof.

In certain embodiments, the first isolation layer 214 may be made of the same material as the second isolation layer 218. In certain embodiments, the first isolation layer 214 may be a softer, more compliant material while the second isolation layer 218 may be harder or the first isolation layer 214 may be made of a soft material that is configured to provide compressibility to the pad assembly 222. The first isolation layer 214 may be made of a polymer material, such as open cell foamed polymers, closed cell foamed polymers, a MYLAR® material, heat activated adhesives, or combinations thereof. The isolation layer 214 may have a hardness of about 60 Shore A to about 100 Shore A.

In certain embodiments, the pad assembly 222 may be formed by compression molding, male/female punch/die, or other methods known in the art to form the first aperture 209, the second plurality of apertures 211, and the plurality of discrete members 205. In this embodiment, the pad base 210 is solid and configured to retain the electrolyte until released through or over a platen lip 258. Alternatively or additionally, at least one of the second plurality of apertures 211 may be extended through the pad base 210 and the upper surface 260 of the platen assembly 230 to allow electrolyte to be drained through the platen assembly 230. In certain embodiments, the plurality of discrete members 205 and the second plurality of apertures 211 may be formed at least to the pad base 210, and the processing surface 125 may be embossed to form an irregular surface on the upper surface of the plurality of discrete members 205. Patterns of channels or grooves may be formed in the upper surface of the plurality of discrete members 205 to aid in electrolyte transportation along the processing surface 125 and facilitate polishing of the substrate 114. Other patterns may include a plurality of small protrusions adjacent shallow depressions in the processing surface 125. The protrusions may take any geometrical form, such as ovals, circles, rectangles, hexagons, octagons, triangles, or combinations thereof and may be formed by compression molding and/or embossment of the processing surface 125. Alternatively, the upper surfaces of each of the plurality of discrete members 205 may be substantially flat or planar having negligible raised or lowered portions on the processing surface 125.

In certain embodiments, the first conductive layer 212 and/or the second conductive layer 216 may be manufactured from a material, such as platinum, copper, stainless steel, titanium, aluminum, gold, silver, tin, nickel, other noble metals, and combinations thereof. In certain embodiments, the first conductive layer 212 and/or the second conductive layer 216 may be manufactured from a core material, such as platinum, copper, stainless steel, titanium, aluminum, gold, silver, tin, nickel, or other cost effective core electrode material, and have outer surfaces of the first conductive layer 212 and the second conductive layer 216 that are in fluid contact with the electrolyte, plated with another metal, such as platinum, titanium, or other electrode material. In certain embodiments, the first conductive layer 212 and the second conductive layer 216 may be fabricated from a conventional polishing material, such as polymer based pad materials compatible with the process chemistry, examples of which include polyurethane, polycarbonate, fluoropolymers, PTFE, PTFA, polyphenylene sulfide (PPS), or combinations thereof. The conventional polishing material may be coated, doped, or impregnated with a process compatible conductive material and/or particles. Alternatively, the conductive material may be a conductive polymer, such as a conductive or dielectric filler material disposed in a conductive polymer matrix or a conductive fabric. In certain embodiments, the conductive material is a polymer matrix having a plurality of conductive particles disposed therein. The conductive particles may be particles made of copper, tin, nickel, gold, silver, platinum, or combinations thereof.

In certain embodiments, the pad base 210 may be an article support layer that provides additional rigidity to the pad assembly 222. The pad base 210 may be fabricated from polymeric materials, for example, polyurethane and polyurethane mixed with fillers, polycarbonate, polyphenylene sulfide (PPS), ethylene-propylene-diene-methylene (EPDM), TEFLON® polymers, or combinations thereof, and other polishing materials used in polishing substrate surfaces, such as open or closed-cell foamed polymer, elastomers, felt, impregnated felt, plastics, and like materials compatible with the processing chemistries. In one embodiment, the pad base 210 is a polyethylene terephthalate (PET) material, and derivatives thereof, such as a MYLAR® polymer sheet. The PET material has a density between about 0.9 grams/cm³ to about 1.45 grams/cm³ and a modulus of elasticity between about 700,000 psi to about 760,000 psi. The pad base 210 material may have a hardness of about 30 Shore A to about 90 Shore A, and is typically harder than the isolation layer 214.

### Processing Pad Articles

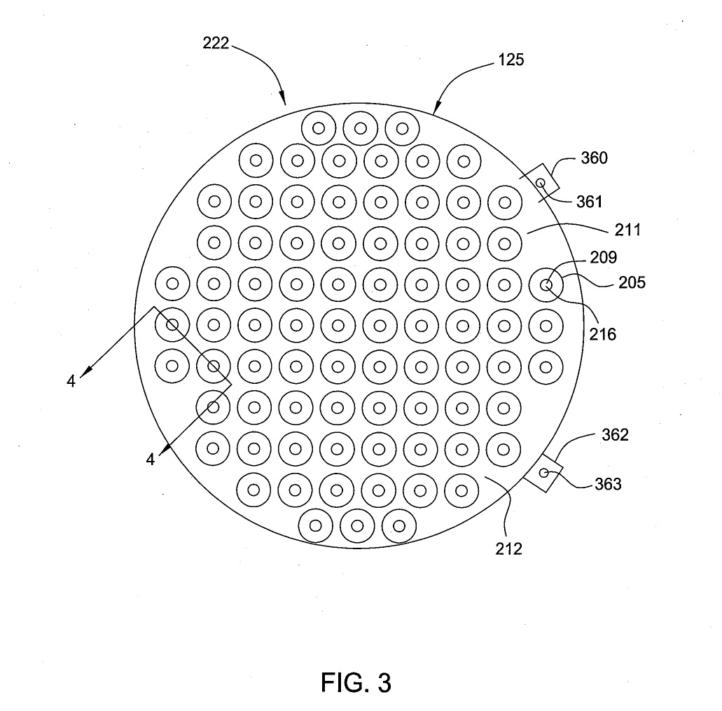

FIG. 3 is a top view of an exemplary pad assembly. The pad assembly 222 shown here as circular includes the plurality of discrete members 205 extending upward from the first conductive layer 212. Each discrete member 205 includes a second conductive layer 216, a first isolation layer (not visible) to electrically isolate the second conductive layer 216 from the first conductive layer 212. The second isolation layer 218 forms the first aperture 209 exposing the second conductive layer 216. Each discrete member 205 is adjacent the plurality of second apertures 211. Also shown is a first connector 360 coupled to the first conductive layer 212 and a second connector 362 coupled to the second conductive layer 216. In certain embodiments, the second connector 362 is individually coupled with each second conductive layer 216 of each discrete member 205. The first and second connectors 360, 362 include a hole 361, 363 respectively, for coupling to a mating electrical connection on the platen assembly 230 and may also facilitate coupling of the pad assembly 222 to the platen assembly 230. In certain embodiments, the first conductive layer 212 functions as an anode and the second conductive layer 216 functions as a cathode. In certain embodiments, the first conductive layer 212 functions as a cathode and the second conductive layer 216 functions as an anode.

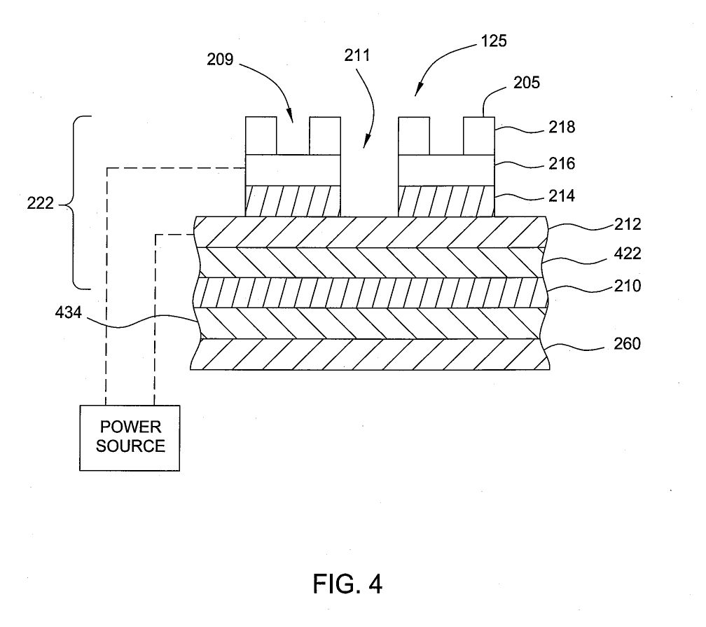

FIG. 4 is a schematic side view taken along line 4-4 of a portion of the exemplary pad assembly 222 of FIG. 3. The pad assembly 222 comprises the processing surface 125 which includes the second plurality of apertures 211 adjacent the plurality of discrete members 205 coupled to an upper surface of the first conductive layer 212. Each discrete member comprises the second isolation layer 218, the second conductive layer 216, and the first isolation layer 214 between the second conductive layer 216 and the first conductive layer 212. The second isolation layer 218 forms the aperture 209 which allows exposure of the second conductive layer 216 to the electrolyte 204. The first conductive layer 212 is coupled to a pad base 210 by a binding layer 422 which is an adhesive that is compatible with process chemistry, such as heat and/or pressure sensitive adhesives known in the art. Other layers of the pad assembly 222 may be coupled by a suitable adhesive. The pad assembly 222 is releasably coupled to the upper surface 260 of the platen assembly by a coupling layer 434 between the upper surface 260 and the lower surface of the pad base 210. The coupling layer 434 may be an adhesive, a hook and loop connector, or any other binder known in the art configured to provide static placement and facilitate replacement of the pad assembly 222.

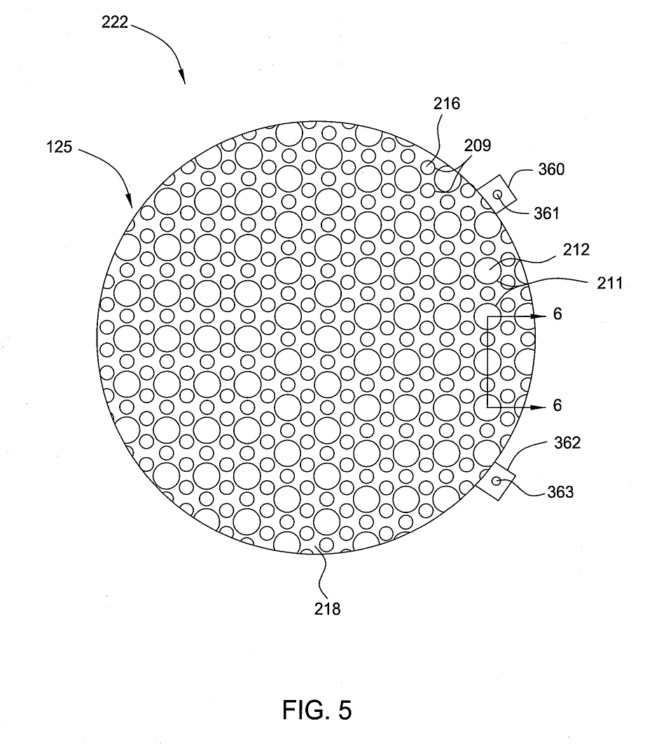

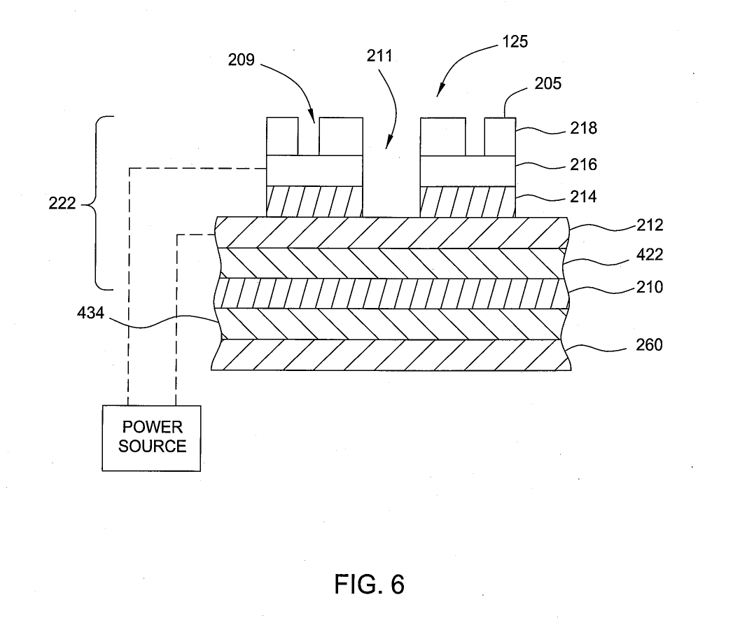

FIG. 5 is a top view of an exemplary pad assembly. FIG. 6 is a schematic side view of a portion of the exemplary pad assembly of FIG. 5 taken along line 6-6. With reference to FIG. 5 and FIG. 6, the pad assembly 222 shown here is circular and comprises the processing surface 125. The pad assembly of FIG. 5 and FIG. 6 is similar to the pad assembly of FIG. 3 and FIG. 4 with the exception that the first isolation layer 214, the second conductive layer 216, and the second isolation layer 218 are continuous and as a result, these layers do not form discrete posts. The processing surface 125 comprises a second isolation layer 218 which forms a first plurality of apertures 209 and a second plurality of apertures 211. The first plurality of apertures 209 expose a first conductive layer 212 and the second plurality of apertures 211 expose a second conductive layer 216. In certain embodiments, the first conductive layer 212 functions as an anode and the second conductive layer 216 functions as a cathode. In certain embodiments, the first conductive layer 212 functions as a cathode and the second conductive layer 216 functions as an anode. A first isolation layer 214 electrically isolates the second conductive layer 216 from the first conductive layer 212. The second isolation layer 218 forms the first plurality of apertures 209 exposing the second conductive layer 216. The second plurality of apertures 211 extends through the second isolation layer 218, the second conductive layer 216, and the first isolation layer (not visible) to expose the first conductive layer 212. Also shown is a first connector 360 coupled to the first conductive layer 212 and a second connector 362 coupled to the second conductive layer 216. The first and second connectors 360, 362 include a hole 361, 363 respectively, for coupling to a mating electrical connection on the platen assembly 230 and may also facilitate coupling of the pad assembly 222 to the platen assembly 230.

### Polishing Process:

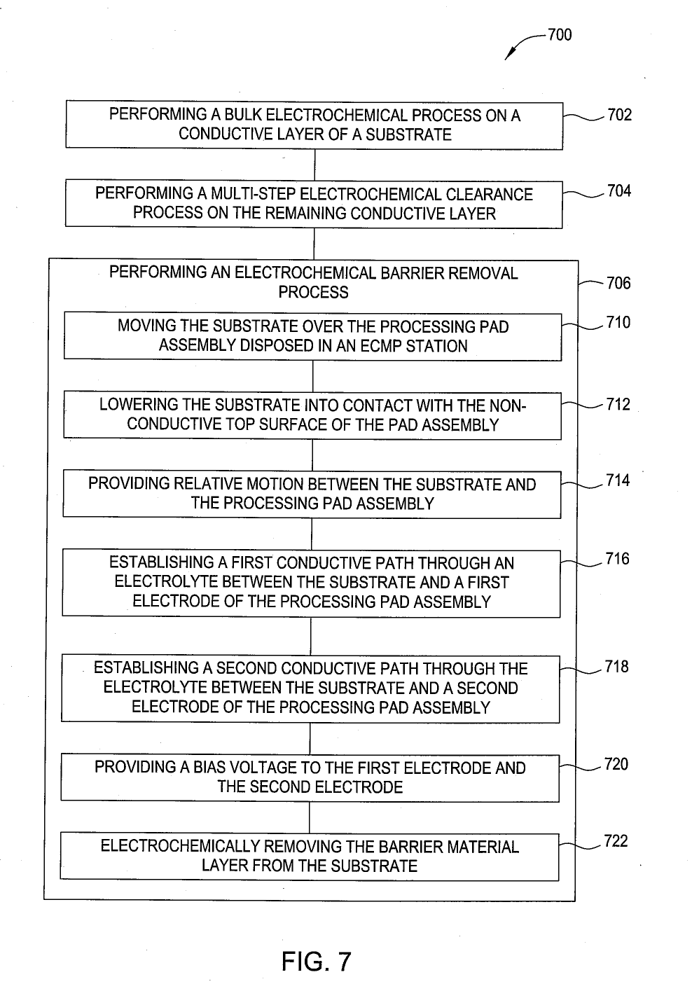

FIG. 7 is a flow diagram of an exemplary method 700 for electroprocessing a substrate having an exposed conductive layer and an underlying barrier material that may be practiced on the system 100 described above. The conductive layer may be tungsten, copper, a layer having exposed tungsten and copper, aluminum, titanium, and the like. The barrier layer may be ruthenium, tantalum, tantalum nitride, titanium, titanium nitride, and the like. A dielectric layer, typically an oxide generally underlies the barrier layer. The method 700 may also be practiced on other electroprocessing systems. Although this exemplary method is discussed with regards to removal of barrier material, it should be understood by one of ordinary skill in the art that the methods and apparatus described herein are equally applicable to the removal of conductive materials.

The method 700 begins at step 702 by performing a bulk electrochemical process on the conductive layer formed on the substrate 114. In one embodiment, the conductive layer is a layer of copper about 6000-8000 Å thick. The bulk process step 702 is performed at the first ECMP station 102. The bulk process step 702 generally is terminated when the conductive layer is about 2000 to about 500 Å thick. Examples of suitable polishing compositions and methods for bulk electrochemical processes are described in U.S. Pat. No. 7,128,825, entitled METHOD AND COMPOSITION FOR POLISHING A SUBSTRATE, issued Oct. 31, 2006 to Liu, et al. and U.S. patent application Ser. No. 11/356,352, entitled METHOD AND COMPOSITION FOR POLISHING A SUBSTRATE, published as U.S. 2006-0169597, both of which are herein incorporated by reference to the extent not inconsistent with the current application.

Next, a multi-step electrochemical clearance step 704 is performed to remove the remaining copper material to expose an underlying barrier layer, which, in certain embodiments, is titanium or titanium nitride. The clearance step 704 may be performed on the first ECMP station 102 or one of the other ECMP stations 103, 106. Examples of suitable polishing compositions and methods for residual electrochemical processes are described in U.S. patent application Ser. No. 10/845,754, entitled METHOD AND COMPOSITION FOR FINE COPPER SLURRY FOR LOW DISHING ECMP, published as U.S. 2004-0248412, U.S. patent application Ser. No. 11/123,274, entitled PROCESS AND COMPOSITION FOR CONDUCTIVE MATERIAL REMOVAL BY ELECTROCHEMICAL MECHANICAL POLISHING, published as U.S. 2005-0218010, and U.S. patent application Ser. No. 11/251,630, entitled PROCESS AND COMPOSITION FOR ELECTROCHEMICAL MECHANICAL POLISHING, published as U.S. 2006-0249394, all of which are herein incorporated by reference to the extent not inconsistent with the current application.

Following the clearance step 704, an electrochemical barrier removal step 706 is performed. Typically, the electrochemical barrier removal step 706 is performed on the third ECMP station 106, but may alternatively be performed on one of the other ECMP stations 102, 104.

The electrochemical barrier removal step 706 begins at step 710 by moving the substrate 114 retained in the carrier head 186 over the processing pad assembly 222 disposed in the third ECMP station 106. At step 712, the carrier head 186 is lowered toward the platen assembly 230 to place the substrate 114 in contact with the processing surface 125 of the pad assembly 222. The barrier material exposed on the substrate 114 is urged against the pad assembly 222 with a force preferably between about 0.05 psi and about 2 psi, more preferably between about 0.1 psi and about 0.8 psi.

At step 714, relative motion between the substrate 114 and processing pad assembly 222 is provided. In one embodiment, the carrier head 186 is rotated at about 30-60 revolutions per minute, while the pad assembly 222 is rotated at about 7-35 revolutions per minute.

At step 716, electrolyte is supplied to the processing pad assembly 222 to establish a first conductive path therethrough between the substrate 114 and the first conductive layer 212. At step 718, a second conductive path is established through the electrolyte between the substrate and the second conductive layer 416. In certain embodiments, step 716 and step 718 occur simultaneously. The electrolyte composition utilized for barrier removal may be different than the electrolyte utilized for copper removal. Examples of suitable polishing compositions for barrier removal are described in U.S. patent application Ser. No. 11/556,593, entitled METHOD AND COMPOSITION FOR ELECTROCHEMICALLY POLISHING A CONDUCTIVE MATERIAL ON A SUBSTRATE and U.S. patent application Ser. No. 10/948,958, entitled METHOD AND COMPOSITION FOR POLISHING A SUBSTRATE, published as U.S. 2006-0021974, both of which are herein incorporated by reference to the extent not inconsistent with the current specification. In certain embodiments, the electrolyte composition provided at the third ECMP station 106 includes phosphoric or sulfuric acid and a catalyst. The electrolyte may be adapted to prevent or inhibit oxide formation on the barrier layer. The catalyst is selected to activate the Ti or other barrier layer to react selectively with a complexing agent so that the barrier layer may be removed and/or dissolved easily with minimal or no removal of copper or tungsten. The electrolyte composition may additionally include pH adjusters and chelating agents, such as amino acids, organic amines and phthalic acid or other organic carbolic acids, picolinic acid or its derivatives. The electrolyte may optionally contain abrasives. Abrasives may be desirable to remove a portion of the underlying oxide layer.

At a first barrier process step 720, a bias voltage is provided from the power source 242 to the first conductive layer 212 and the second conductive layer 216. In certain embodiments, a negative bias is applied to the first conductive layer 212, which functions as a cathode, and a positive bias is applied to the second conductive layer 216, which functions as an anode. In certain embodiments, a positive bias is applied to the first conductive layer 212 which functions as an anode, and a negative bias is applied to the second conductive layer 216, which functions as the cathode. The voltage applied to the first conductive layer 212 and second conductive layer 216 is preferably between about 0 volts and about 20 volts, and more preferably between about 2 volts and about 8 volts. A first conductive path is established through the electrolyte filling the first aperture 209 between the substrate 114 and the second conductive layer 216 to drive an electrochemical mechanical planarizing process. A second conductive path is established through the electrolyte filling the second plurality of apertures between the first conductive layer 212 and the substrate 114 to further drive the electrochemical process. At step 722, the barrier material is electrochemically removed from the substrate. The process of step 722 generally has a removal rate of about 500 to about 2,000 Å/min. Removal rates for other barrier materials are comparable.

In a typical ECMP process, the substrate is controllably urged against the processing surface of the pad assembly which typically comprises an anode. Thus the substrate and the anode have the same potential. However, due to the inert nature of most barrier materials, the removal current during Ecmp barrier removal processes is very low. The removal current may be increased by increasing the applied voltage; however, an increase in the applied voltage to the anode generally leads to a large leakage current between the electrodes. The current invention eliminates direct contact between the anode and the substrate. The lack of direct contact between the anode and the substrate allows for the application of high voltage to the anode, while reducing leakage current, thus causing a voltage drop between the substrate and the cathode which drives the removal of barrier materials.

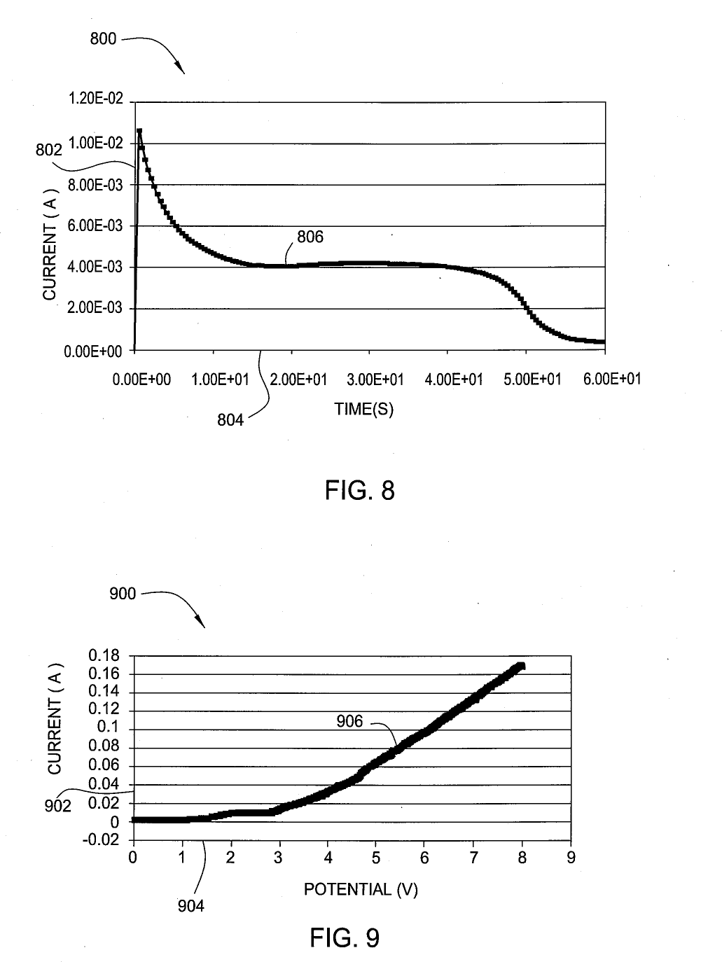

FIG. 8 depicts a graph 800 illustrating current verses time for one embodiment of an exemplary electroprocessing method. Current (amperes) is plotted on the Y-axis 802 and time (seconds) is plotted on the X-axis 804. The current-time curve 806 for TiN polished at 8V in an electrolyte. It only takes less than a minute to remove 300 Å TiN film from a silicon substrate.

FIG. 9 depicts a graph 900 illustrating current verse voltage for copper polished in an electrolyte with abrasion. Current (amperes) is plotted on the Y-axis 902 and potential (voltage) is plotted on the X-axis 904. The current-voltage curve 906 demonstrates that the current increase with increased potential.

Thus, the present invention provides an improved apparatus and method for electrochemically planarizing a substrate. The apparatus advantageously facilitates efficient bulk and residual metal and barrier materials removal from a substrate using a single tool. Utilization of electrochemical processes for full sequence metal and barrier removal advantageously provides low erosion and dishing of conductors while minimizing oxide loss during processing. It is contemplated that a method and apparatus as described by the teachings herein may be utilized to deposit materials onto a substrate by reversing the polarity of the bias applied to the electrode and the substrate.

While the foregoing is directed to embodiments of the present invention, other and further embodiments of the invention may be devised without departing from the basic scope thereof, and the scope thereof is determined by the claims that follow.

1. A pad assembly for processing a substrate, comprising:
a first conductive layer;
a first isolation layer coupled with the first conductive layer;
a second conductive layer coupled with the first isolation layer; and
a second isolation layer coupled with the second conductive layer, wherein the second isolation layer forms a processing surface adapted to contact the substrate.

2. The pad assembly of claim 1, wherein the processing surface has a first plurality of apertures defined by openings extending through the second isolation layer, the second conductive layer, and the first isolation layer.

3. The pad assembly of claim 2, wherein the first plurality of apertures exposes the first conductive layer.

4. The pad assembly of claim 1, wherein the second isolation layer has a thickness between about 0.1 mm and about 2 mm.

5. The pad assembly of claim 1, wherein the second isolation layer has a second aperture which exposes the second conductive layer.

6. The pad assembly of claim 1, wherein the first conductive layer is coupled to a negative bias source.

7. The pad assembly of claim 6, wherein the second conductive layer is coupled to a positive bias source.

8. The pad assembly of claim 1, further comprising a pad base disposed below the first conductive layer with a binding layer therebetween.

9. The pad assembly of claim 1, wherein the first conductive layer and the second conductive layer comprise materials selected from the group of copper, titanium, tin, nickel, or stainless steel.

10. The pad assembly of claim 1, wherein the second isolation layer comprises polymeric material such as polyurethane, polyurethane mixed with fillers, polycarbonate, polyphenylsufide, polyethylene terephthalate, ethylene-propylene-diene-methylene, or combinations thereof.

11. A method for electroprocessing a substrate, comprising:
contacting the substrate with the non-conductive surface of a polishing pad assembly;
establishing a first electrically conductive path through an electrolyte between an exposed layer of barrier material and a first electrode;
establishing a second electrically conductive path through the electrolyte between the exposed layer of barrier material and a second electrode;
applying a voltage to the first electrode to cause a voltage drop between the substrate and the second electrode; and
removing the barrier material layer from the substrate.

12. The method of claim 11, wherein applying a voltage to the first electrode comprises applying a positive bias to the first electrode.

13. The method of claim 12, further comprising applying a negative bias to the second electrode.

14. The method of claim 11, wherein the barrier material is at least one of ruthenium, titanium, titanium nitride, tantalum, and tantalum nitride.

15. The method of claim 11, wherein the voltage is between about 2 V and about 8 V.

16. The method of claim 11, further comprising tuning the first electrode and the second electrode to adjust the voltage drop.

17. A method for electroprocessing a substrate, comprising:
providing a pad assembly comprising a first non-conductive layer, a first conductive layer coupled with the non-conductive layer, a second conductive layer, and a second non-conductive layer disposed between the first conductive layer and the second conductive layer;
contacting the substrate with the non-conductive layer of the polishing pad assembly;
establishing a first electrically conductive path through an electrolyte between an exposed layer of barrier material on the substrate and the first conductive layer;
establishing a second electrically conductive path through the electrolyte between the exposed layer of barrier material on the substrate and the second conductive layer;
applying a positive voltage to the first conductive layer;
applying a negative voltage to the second conductive layer; and
removing the barrier material layer from the substrate.

18. The method of claim 17, wherein the barrier material is at least one of ruthenium, titanium, titanium nitride, tantalum, and tantalum nitride.

19. The method of claim 17, further comprising establishing a voltage drop between the substrate and the second conductive layer.

20. The method of claim 17, wherein the positive voltage is between 0 V and about 20 V.
